(19) United States
(12) Patent Application Publication
(10) Pub. No.: US 2018/0080485 A1
(43) Pub. Date: Mar. 22, 2018

(54) QUICK RELEASE CONNECTING DEVICE

(71) Applicant: TING-JUI WANG, New Taipei City (TW)

(72) Inventor: TING-JUI WANG, New Taipei City (TW)

(21) Appl. No.: 15/825,748

(22) Filed: Nov. 29, 2017

Related U.S. Application Data
(63) Continuation-in-part of application No. 14/553,176, filed on Nov. 25, 2014.

(51) Int. Cl. F16B 2/18; E05C 5/00; H05K 7/14

(52) U.S. Cl. CPC F16B 2/185; E05B 65/46; H05K 7/1409; E05C 5/00

(57) ABSTRACT

A quick release connecting device includes an actuating retainer having an internal receiving space, at least one first push section and a retaining section for detachably engaging with a first object; a fixing member including a body portion movably associated with the receiving space and a pivot portion formed on the body portion for detachably connecting with a second object; pin connection means connecting the body portion to the receiving space for the actuating retainer and the fixing member to move relative to each other within a limited range; an elastic element having two ends pressed against an inner wall surface of the receiving space and the body portion to control the limited movement of the actuating retainer and the fixing member and return them to their original positions. With the quick release connecting device, two mating objects can be conveniently repeatedly connected to and separated from each other.

### CROSS-REFERENCE TO RELATED APPLICATION

This application is a continuation-in-part patent application of U.S. application Ser. No. 14/553,176 filed on Nov. 25, 2014, the entire contents of which are hereby incorporated by reference for which priority is claimed under 35 U.S.C. § 120.

### FIELD OF THE INVENTION

The present invention relates to a quick release connecting device, and more particularly to a quick release connecting device that enables convenient and repeated assembling and separation of a circuit board, a drawer, or a window to and from a corresponding rack, chassis, cabinet or window frame.

### BACKGROUND OF THE INVENTION

To enable convenient assembling and fastening of a circuit board to a rack, and to enable easy disassembling of the circuit board from the rack when necessary, a quick release mechanism is usually provided on the circuit board or the rack. Various types of quick release mechanisms are known, and each type of circuit board has a corresponding quick release mechanism designed for it. To enable two mating objects, such as the circuit board and the rack, to be repeatedly assembled to and separated from each other in a quick and convenient manner, it is desirable to develop an improved quick release connecting device that includes means to assist in pushing away a first one of the two mating objects, so that the second object can be easily pulled out of the first object.

### SUMMARY OF THE INVENTION

In view that the prior art quick release mechanisms are not perfect for use, it is tried by the inventor to develop an improved quick release connecting device to enable convenient and repeated assembling and separation of a circuit board, a drawer, a window, etc. to and from a corresponding rack, chassis, cabinet, window frame, etc.

A primary object of the present invention is to provide a quick release connecting device that includes an actuating retainer and a fixing member limitedly movably assembled to each other, so that a second object, such as a circuit board, a drawer or a window, detachably connected to a first object, such as a rack, a chassis, a cabinet or a window frame, via the actuating retainer and the fixing member can be conveniently and repeatedly assembled to and separated from each other.

To achieve the above and other objects, the quick release connecting device according to a preferred embodiment of the present invention includes an actuating retainer having an internal receiving space and a retaining section for detachably engaging with a first object; a fixing member including a body portion movably associated with the receiving space and a pivot portion formed on the body portion for detachably connecting with a second object; pin connection means connecting the body portion to the receiving space for the actuating retainer and the fixing member to move relative to each other within a limited range; and an elastic element disposed in the receiving space with two ends pressed against an inner wall surface of the receiving space and the body portion to control the limited movement of the actuating retainer and the fixing member and return them to their original positions. Or, according to another operable embodiment, the actuating retainer includes at least one first push section, a body portion and a retaining section for detachably engaging with a first object; the fixing member internally defines a receiving space and includes a pivot portion formed on an outer side of the receiving space; the body portion of the actuating retainer is movably received in the receiving space of the fixing member, and the pivot portion is used to movably connect to a second object; the pin connection means enables connection of the receiving space of the fixing member to the body portion of the actuating retainer, such that the actuating retainer and the fixing member are movable relative to each other within a limited range; and the elastic element is disposed in the receiving space of the fixing member with an end pressed against an inner wall surface of the receiving space and another opposite end against the body portion of the actuating retainer, such that the elastic element enables and controls the limited movement of the actuating retainer and the fixing member relative to each other and can elastically push the actuating retainer and the fixing member back to their original positions; and the fixing member includes a second push section having a first push part or a second push part; the first push part or the second push part is able to push against a third object; and the push of the second push section against the third object causes a lever displacement, a rotary displacement or a limited displacement of the third object to thereby open, close, forward move or backward move the third object.

To achieve the above and other objects, the quick release connecting device according to another preferred embodiment of the present invention includes an actuating retainer internally defining a receiving space and including at least one first push section and a retaining section for detachably engaging with a first object; a fixing member being movably assembled to the actuating retainer and including a body portion and a pivot portion formed on an outer end of the body portion, the body portion having an inner end movably associated with the receiving space of the actuating retainer, and the pivot portion being located outside the receiving space for detachably connecting with a second object; pin connection means enabling connection of the body portion of the fixing member to the receiving space of the actuating retainer, such that the actuating retainer and the fixing member are movable relative to each other within a limited range; and an elastic element being disposed in the receiving space of the actuating retainer with an end pressed against an inner wall surface of the receiving space and another opposite end against the body portion of the fixing member; wherein the elastic element enables and controls limited movement of the actuating retainer and the fixing member relative to each other, and can push the actuating retainer and the fixing member back to their original positions when the second object is separated from the first object and the first push section of the actuating retainer is no longer subjected to a push. Or, according to another operable embodiment, the actuating retainer includes at least one first push section, a body portion and a retaining section for detachably engaging with a first object; the fixing member internally defines a receiving space and includes a pivot portion formed on an outer side of the receiving space; the body portion of the actuating retainer is movably received in the receiving space of the fixing member, and the pivot portion is used to movably connect to a second object; the pin connection means enables connection of the receiving space of the fixing member to the body portion of the actuating retainer, such that the actuating retainer and the fixing member are movable relative to each other within a limited range; and the elastic element is disposed in the receiving space of the fixing member with an end pressed against an inner wall surface of the receiving space and another opposite end against the body portion of the actuating retainer, such that the elastic element enables and controls the limited movement of the actuating retainer and the fixing member relative to each other and can elastically push the actuating retainer and the fixing member back to their original positions; and the fixing member includes a second push section having a first push part or a second push part. In practical use of the first push part or the second push part, the first push part or the second push part is first subjected to a rotational or a non-rotational displacement to be located in front of, behind or in the middle of a location where a third object will be pushed against or interfered with, such that the first push part or the second push part having been rotationally or non-rotationally displaced can push against or interfere with the third object, enabling the second push section to open, close, forward move or backward move the third object through a lever displacement, a rotary displacement or a limited displacement of the third object.

In an operable embodiment of the quick release connecting device according to the present invention, the fixing member includes a hand push section formed on the body portion.

In an embodiment of the quick release connecting device of the present invention, the actuating retainer and the fixing member connected to each other via the pin connection means are slidable relative to each other within a limited range.

In the above embodiment of the quick release connecting device of the present invention, the actuating retainer includes a pin connection slot communicating with the receiving space, and the pin connection means is located in the pin connection slot.

In an operable embodiment of the quick release connecting device of the present invention, the pin connection slot is a long slide slot formed on one or two lateral walls of the receiving space; and the pin connection means is slidable in the long slide slot to thereby bring the actuating retainer and the fixing member to slide relative to each other within a limited range.

In another embodiment of the quick release connecting device of the present invention, the body portion of the fixing member includes a long slide hole communicable with the receiving space; and the pin connection means is slidable in the long slide hole to thereby bring the actuating retainer and the fixing member to slide relative to each other within a limited range.

In an embodiment of the quick release connecting device of the present invention, the actuating retainer and the fixing member connected to each other via the pin connection means are rotatable relative to each other within a limited angle.

In the above embodiment of the quick release connecting device of the present invention, the actuating retainer includes a pin connection slot communicating with the receiving space, and the pin connection means is located in the pin connection slot.

In an operable embodiment of the quick release connecting device of the present invention, the pin connection slot is a locating hole formed on one or two lateral walls of the receiving space; and the pin connection means is rotatable in the locating hole to thereby bring the actuating retainer and the fixing member to rotate relative to each other within a limited angle.

In an embodiment of the quick release connecting device of the present invention, the pin connection means includes a cylindrical pin integrally formed with or additionally assembled to the body portion of the fixing member.

In the above embodiment of the quick release connecting device of the present invention, the pin connection means further includes a pin holding hole formed on the body portion of the fixing member; and the cylindrical pin is inserted in, riveted to, expansion-fitted in, glued to or screwed into the pin holding hole.

In an embodiment of the quick release connecting device of the present invention, the pin connection means includes a cylindrical pin integrally formed with or additionally assembled to the actuating retainer.

In the above embodiment of the quick release connecting device of the present invention, the pin connection means further includes a pin holding hole formed on the actuating retainer; and the cylindrical pin is inserted in, riveted to, expansion-fitted in, glued to or screwed into the pin holding hole.

In another embodiment of the quick release connecting device of the present invention, the pin connection means includes a cylindrical pin integrally formed with or additionally assembled to the actuating retainer; and the cylindrical pin is transversely extended through the receiving space.

In the above embodiment of the quick release connecting device of the present invention, the pin connection means further includes at least one pin holding hole formed on the actuating retainer to communicate with the receiving space; and the cylindrical pin is inserted in, riveted to, expansion-fitted in, glued to or screwed into the pin holding hole.

In an embodiment of the quick release connecting device of the present invention, the retaining section on the actuating retainer can be any one of a hook, a recessed section, a protruded section, a stepped section, a flat surface, a cambered surface and a curved surface directed leftward or rightward or forward relative to the actuating retainer.

In the above embodiment of the quick release connecting device of the present invention, the retaining section includes a beveled guide surface for guiding the actuating retainer into the first object to engage with the first object.

In an embodiment of the quick release connecting device of the present invention, the actuating retainer includes at least one first push section.

In an embodiment of the quick release connecting device of the present invention, the fixing member includes at least one second push section.

In an embodiment of the quick release connecting device of the present invention, the receiving space includes a slide space, and the body portion of the fixing member is movable in the slide space.

In an embodiment of the quick release connecting device of the present invention, the elastic element is a coil spring, a spring plate or an elastic bar.

In an embodiment of the quick release connecting device of the present invention, the pivot portion of the fixing member can be one of a protruded block, a retaining block and a through hole integrally formed with or additionally assembled to the body portion.

In an embodiment of the quick release connecting device of the present invention, the pivot portion is inserted in, snapped fitted onto, riveted to, expansion-fitted onto or screwed to the second object to be movably connected to the second object.

In the quick release connecting device of the present invention, the actuating retainer and the fixing member are made of a material selected from the group consisting of a plastic material and a metal material.

In the quick release connecting device of the present invention, the pivot portion can have a pivot member movably mounted thereto for coupling with the second object.

In the quick release connecting device of the present invention, the pivot member can include a shaft movably assembled thereto.

In the quick release connecting device of the present invention, the pivot member and the shaft can be movably assembled together via second pin connection means, or the fixing member and the shaft can be movably assembled together via second pin connection means.

In the quick release connecting device of the present invention, the pivot portion or the pivot member has an elastic element fitted thereon, the elastic element either has two ends pressed against the pivot member and the fixing member of the quick release connecting device or has two ends pressed against the quick release connecting device and the second object, such that the fixing member under a spring force of the elastic element is either automatically sprung back to its original position or be limited to a fixed position.

In the quick release connecting device of the present invention, the fixing member includes a limiting section and the pivot member includes a corresponding limiting section; and the limiting section and the corresponding limiting section are able to limit or stop each other at a specific location when the fixing member is moved or rotated.

In the quick release connecting device of the present invention, the first push section can be a boss, a bore, a recess, a protrusion, a fastener, a stepped section, an anti-slip section, a flat section, a hook section or a cambered section.

In the quick release connecting device of the present invention, the pivot member can include a coupling section for screwing onto, snap-fitted on, expansion-fitted on, welded to or riveted to the second object.

In the quick release connecting device of the present invention, the actuating retainer or the body portion thereof can include a shoulder section for limiting a distance by which the actuating retainer or the body portion thereof is allowed to move into the receiving space of the fixing member.

In the quick release connecting device of the present invention, the first object and the second object can be integrally formed, assembled together, or two independent objects.

In the quick release connecting device of the present invention, the quick release connecting device and the second object can be assembled together to form a module.

In the quick release connecting device of the present invention, the second object can include a limiting section for limiting a distance or an angle by which the second push section can be moved or rotated, respectively.

In the quick release connecting device of the present invention, the first push section of the actuating retainer is operable to compress the first push section toward the fixing member, such that an overall travel of the quick release connecting device is shortened and the retaining section of the actuating retainer is separated from the first object to pull the second object.

In the quick release connecting device of the present invention, the second push section can be any one of a protruded section, a recessed section, a through bore, a stepped section, a flat section, a cambered section, a hook section and a curved section.

To use the quick release connecting device of the present invention, first movably connect the pivot portion of the fixing member to the second object, such as a circuit board, a drawer or a window. Since the actuating retainer and the fixing member are movably assembled to each other, at least one of them can be quickly detachably engaged with at least a first object, such as a chassis, a rack, a cabinet or a window frame. More specifically, the retaining section of the actuating retainer and/or the second push section of the fixing member can be quickly detachably engaged with the first object to thereby quickly connect the second object to the first object. On the other hand, to separate the second object from the first object, simply push the first push section for the retaining section to disengage from the first object and pivotally turn the fixing member for the second push section to push away the first object, and the second object is easily separated from the first object. Therefore, with the quick release connecting device of the present invention, the second object can be repeatedly quickly assembled to and separated from the first object.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a quick release connecting device according to a first preferred embodiment of the present invention;

FIG. 2 is an exploded view of FIG. 1;

FIG. 3 is a partially sectioned front view of FIG. 1;

FIG. 4 is a sectional view taken along line A-A of FIG. 3;

FIG. 5 is an assembled front view of a first variant of the quick release connecting device according to the first preferred embodiment of the present invention, showing it further includes a hand push section;

FIG. 6 is an assembled perspective view of a second variant of the first preferred embodiment of the present invention;

FIG. 7 is an exploded view of FIG. 6;

FIG. 8 is a partially sectioned front view of FIG. 6;

FIG. 9 is a partially sectioned front view of a third variant of the first preferred embodiment of the present invention, showing two first push sections are included in the quick release connecting device;

FIG. 10 is an assembled partially sectioned front view of a quick release connecting device according to a second preferred embodiment of the present invention;

FIG. 11 is an assembled perspective view of the quick release connecting device according to the second preferred embodiment of the present invention;

FIG. 12 is an assembled partially sectioned front view of a variant of the second preferred embodiment of the present invention, showing an elastic plate and a different retaining section are included in the quick release connecting device;

FIG. 13A shows the quick release connecting device according to the first preferred embodiment of the present invention is connected to two objects and can be operated to quickly release the two objects from each other;

FIG. 13B shows the quick release connecting device according to the first preferred embodiment of the present invention is connected to two objects and can be operated to quickly release the two objects from each other;

FIG. 13C shows the quick release connecting device according to the first preferred embodiment of the present invention is connected to two objects and can be operated to quickly release the two objects from each other;

FIG. 13D shows the quick release connecting device according to the first preferred embodiment of the present invention is connected to two objects and can be operated to quickly release the two objects from each other;

FIG. 14A shows the quick release connecting device according to the second preferred embodiment of the present invention is connected to two objects and can be operated to quickly release the two objects from each other;

FIG. 14B shows the quick release connecting device according to the second preferred embodiment of the present invention is connected to two objects and can be operated to quickly release the two objects from each other;

FIG. 14C shows the quick release connecting device according to the second preferred embodiment of the present invention is connected to two objects and can be operated to quickly release the two objects from each other;

FIG. 14D shows the quick release connecting device according to the second preferred embodiment of the present invention is connected to two objects and can be operated to quickly release the two objects from each other;

FIG. 15 is an exploded perspective view of a quick release connecting device according to a third preferred embodiment of the present invention;

FIG. 16 is an assembled top view of a quick release connecting device according to a fourth preferred embodiment of the present invention;

FIG. 17 is an assembled top view of a quick release connecting device according to a fifth preferred embodiment of the present invention;

FIG. 18 shows a quick release connecting device according to a sixth preferred embodiment of the present invention;

FIG. 19 shows a quick release connecting device according to a sixth preferred embodiment of the present invention;

FIG. 20 shows a quick release connecting device according to a seventh preferred embodiment of the present invention; and

FIG. 21 shows a quick release connecting device according to a seventh preferred embodiment of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

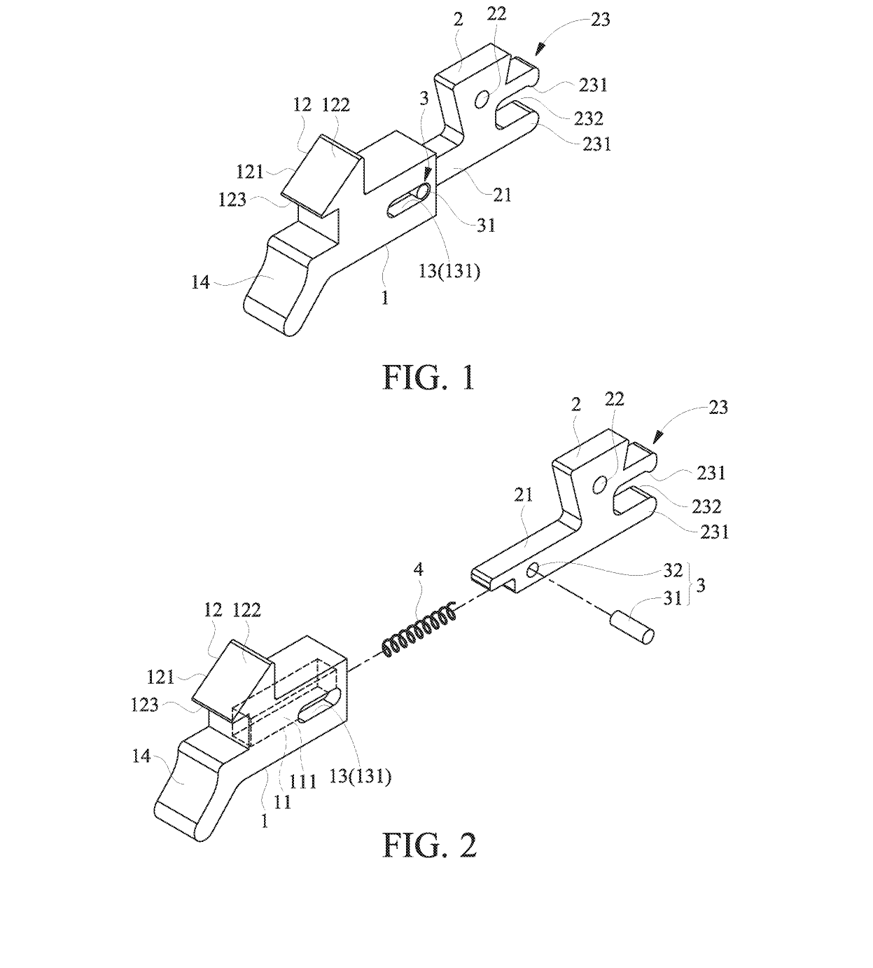

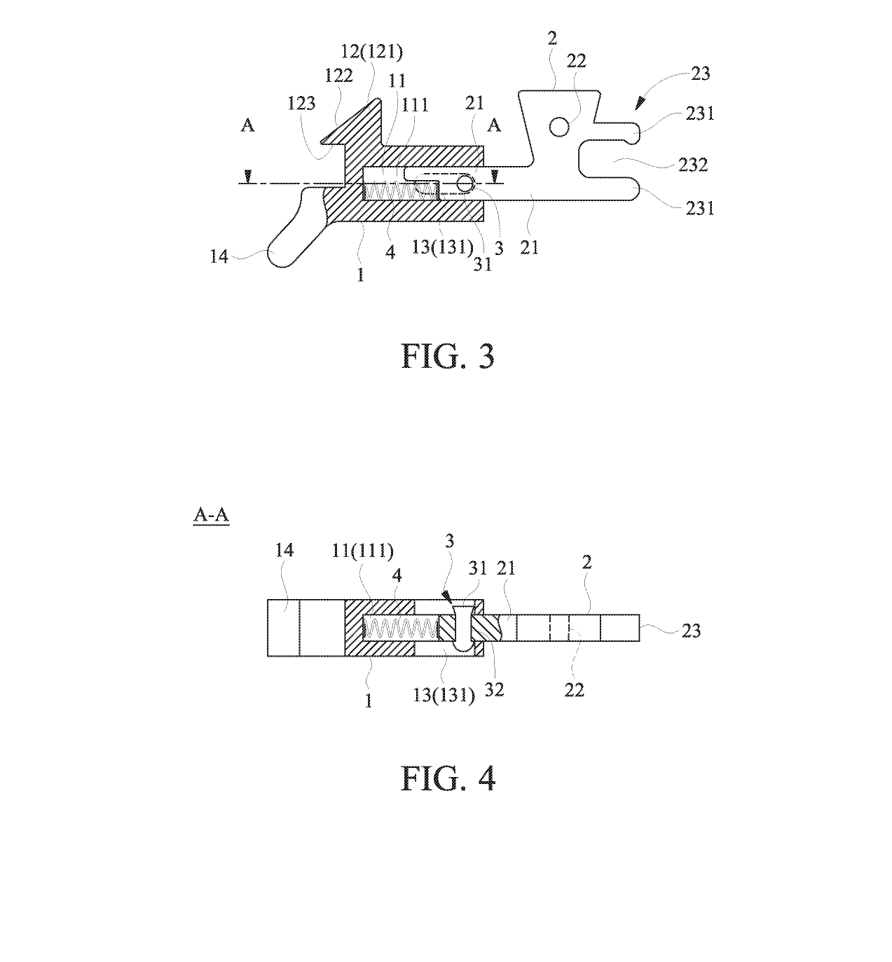

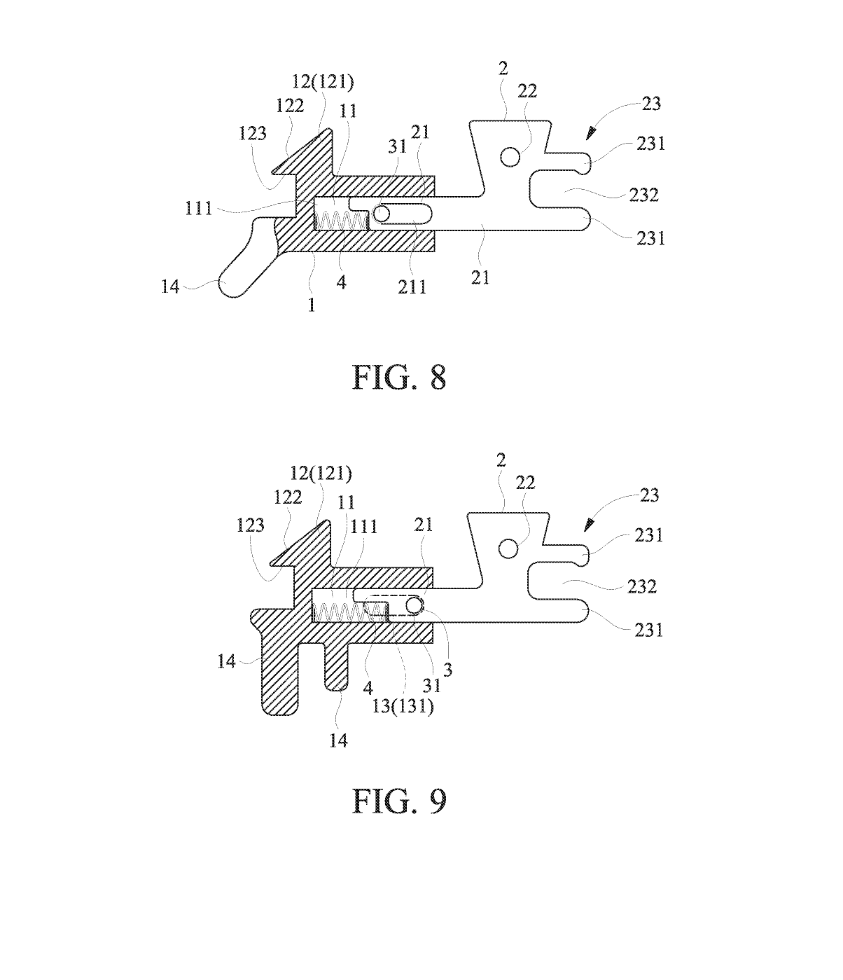

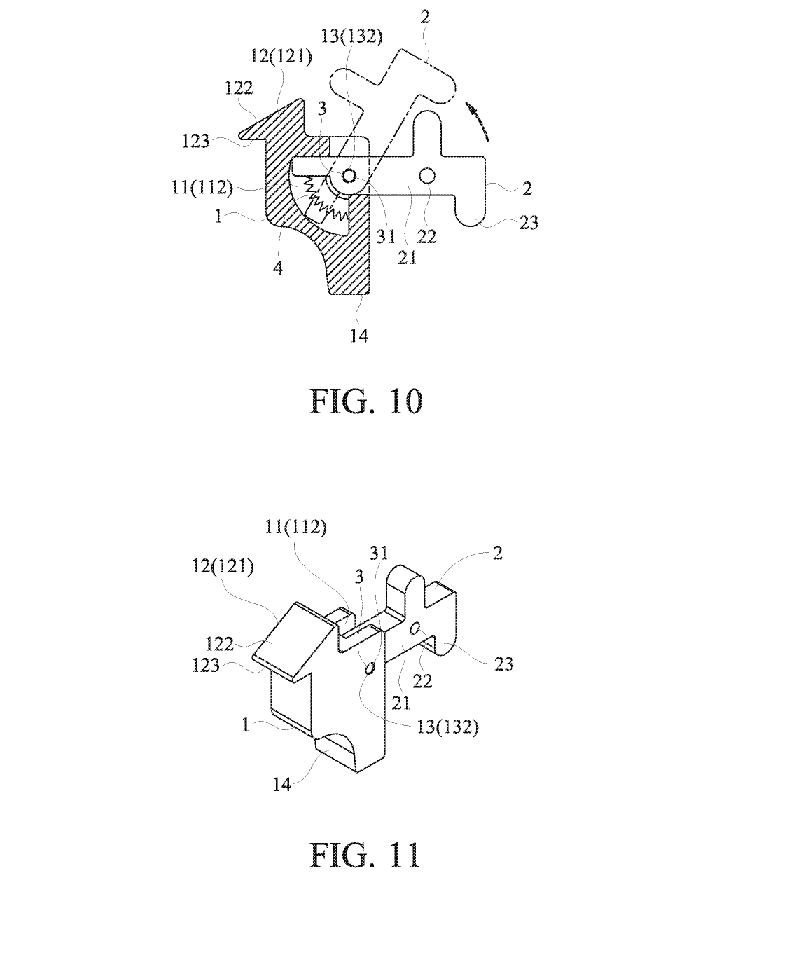

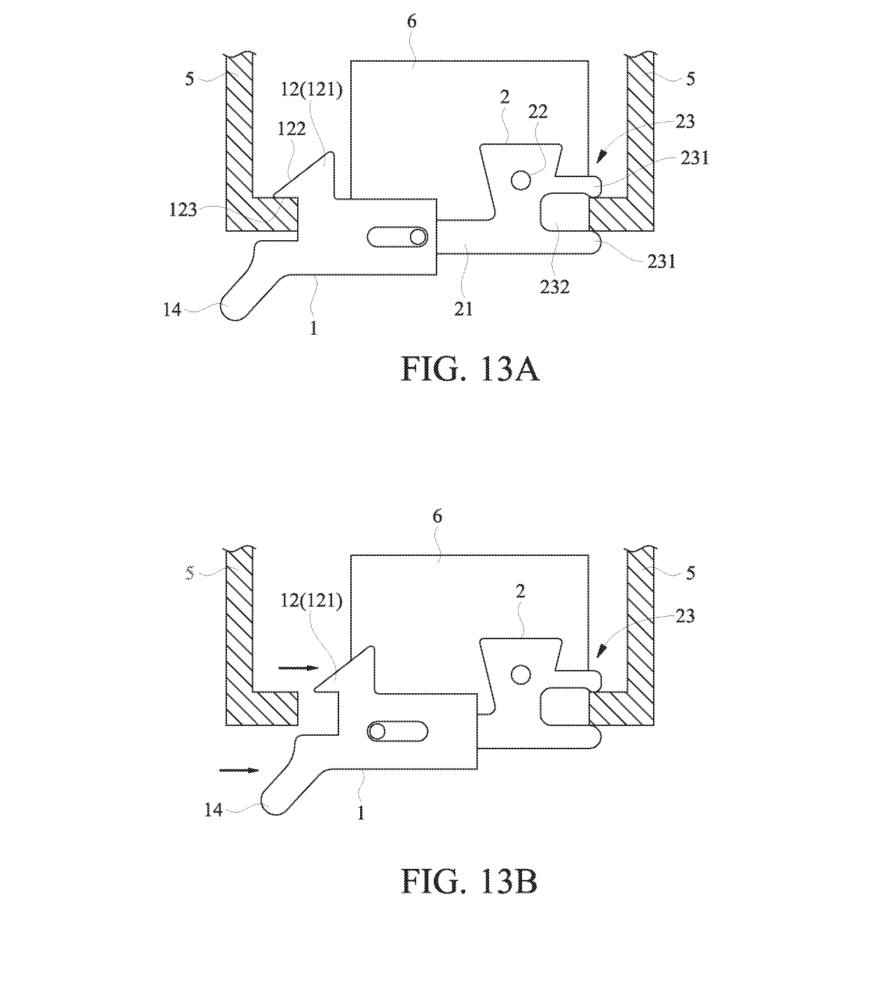

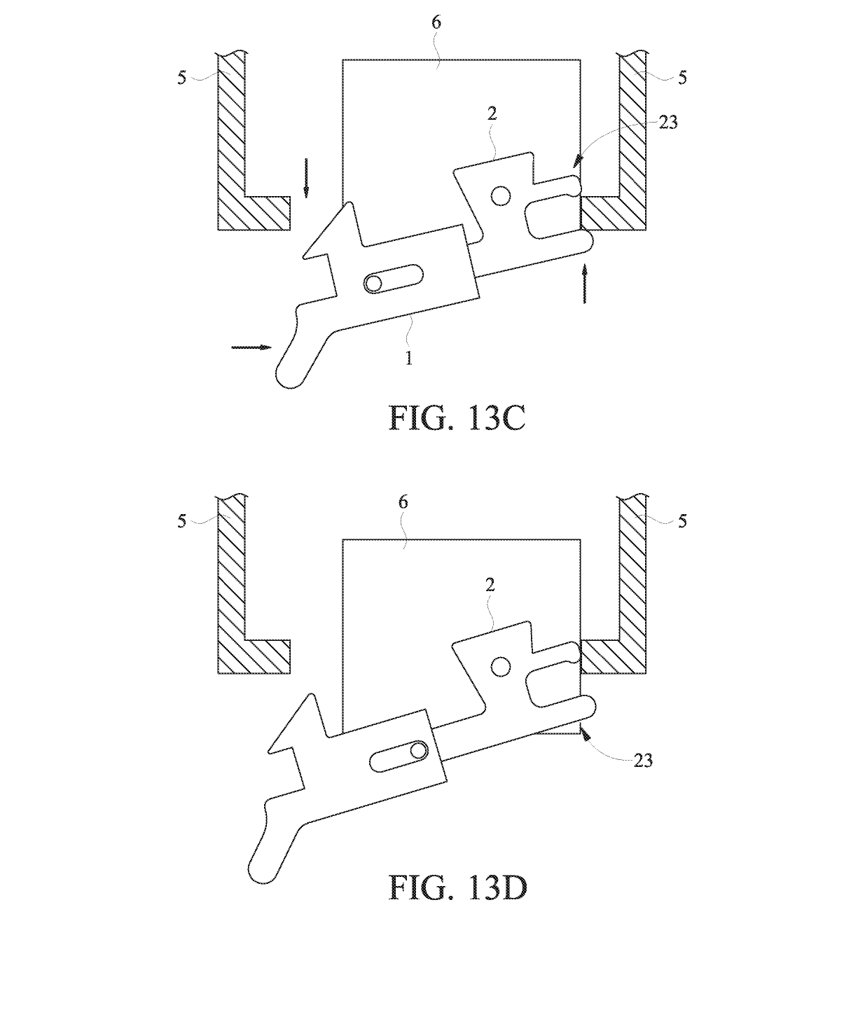

FIGS. 1 to 9 show a quick release connecting device according to a first preferred embodiment of the present invention, which is configured to enable limited slide, i.e. to slide within a limited range; and FIGS. 10 to 12 show a quick release connecting device according to a second preferred embodiment of the present invention, which is configured to enable limited rotation, i.e. to rotate within a limited angle. As shown, in both of the first and second preferred embodiments, the quick release connecting device of the present invention includes an actuating retainer 1 and a fixing member 2 movably assembled to the actuating retainer 1. The actuating retainer 1 can be made of a plastic material or a metal material; it internally defines a receiving space 11 and includes a retaining section 12 for detachably engaging with a first object 5 and at least one first push section 14. The fixing member 2 can be made of a plastic material or a metal material; it includes a body portion 21 and a pivot portion 22 formed on an outer end of the body portion 21. The body portion 21 has an inner end movably associated with the receiving space 11 of the actuating retainer 1; and the pivot portion 22 is located outside the receiving space 11 for detachably connecting with a second object 6. The first push section 14 can be a protrusion outward projected from any side of the actuating retainer 1. As shown in FIG. 13B, by applying a force against the first push section 14, the actuating retainer 1 can be moved to release the retaining section 12 from the first object 5, allowing the second object 6 to separate from the first object 5. The quick release connecting device of the present invention further includes pin connection means 3 and an elastic element 4. The pin connection means 3 enables connection of the body portion 21 of the fixing member 2 to the receiving space 11 of the actuating retainer 1, such that the actuating retainer 1 and the fixing member 2 in the first and the second preferred embodiment are slidable and rotatable, respectively, relative to each other within a limited range and angle. The elastic element 4 is disposed in the receiving space 11 of the actuating retainer 1, or can be disposed at a selected position, with an end pressed against an inner wall surface of the receiving space 11 and another opposite end against the body portion 21 of the fixing member 2. The elastic element 4 enables and controls limited sliding or rotation of the actuating retainer 1 and the fixing member 2 relative to each other, and can elastically push the actuating retainer 1 and the fixing member 2 back to their original positions.

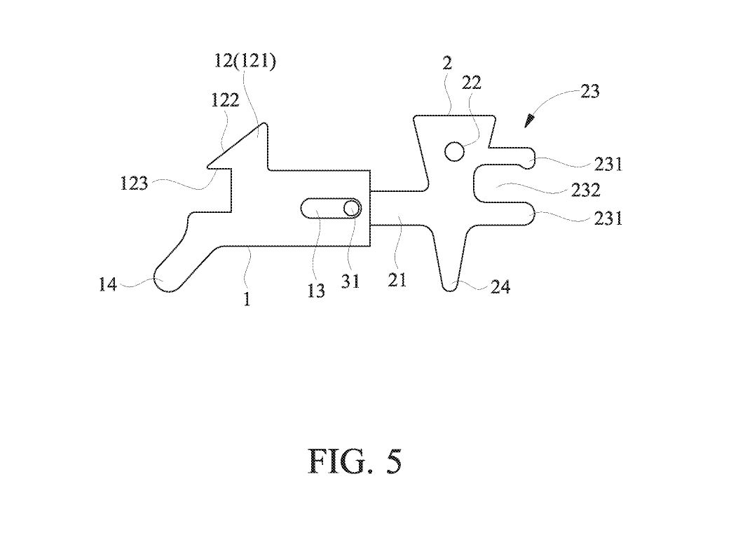

Please refer to FIG. 5 that is an assembled front view showing a first variant of the first preferred embodiment of the present invention further includes a hand push section 24 provided on the body portion 21 of the fixing member 2. The hand push section 24 can be a protrusion downward projected from a lower side of the body portion 21. The hand push section 24 and the first push section 14 are preferably directed to the same direction. In FIG. 5, the hand push section 24 and the first push section 14 are illustrated as directing downward. With this arrangement, a user may conveniently move the actuating retainer 1 toward the fixing member 2 by pressing one finger, such as the thumb, against an axially outer side (i.e. the left side in the drawing) of the first push section 14 while pressing another finger, such as the index finger, against an axially outer side (i.e. the right side in the drawing) of the hand push section 24.

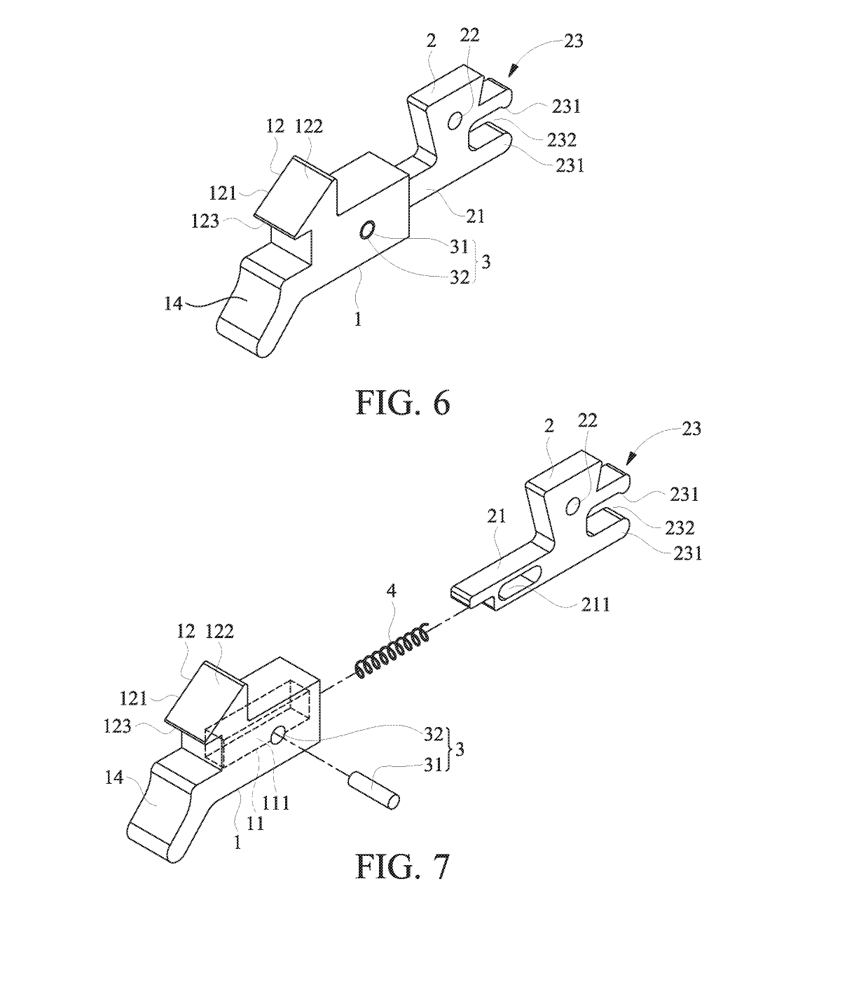

Please refer to FIGS. 1 to 4, in which the quick release connecting device according to the first preferred embodiment of the present invention is shown. As shown, in the first preferred embodiment, the actuating retainer 1 and the fixing member 2 are held to each other via the pin connection means 3 to allow limited sliding of them relative to each other, and accordingly, the retaining section 12 is slidably engaged with or released from the first object 5. More specifically, the actuating retainer 1 is internally provided with a pin connection slot 13, which communicates with the receiving space 11, and the pin connection means 3 is located in the pin connection slot 13. The pin connection slot 13 can be a long slide slot 131 formed on one or two lateral walls of the receiving space 11. When the pin connection means 3 slides in the long slide slot 131, the actuating retainer 1 and the fixing member 2 are brought to slide relative to each other within a limited range. FIGS. 6 to 8 show a second variant of the quick release connecting device according to the first preferred embodiment of the present invention. In the second variant, the body portion 21 of the fixing member 2 is formed with a long slide hole 211, which is communicable with the receiving space 11, and the pin connection means 3 is slidable in the long slide hole 211 to thereby bring the actuating retainer 1 and the fixing member 2 to slide relative to each other within a limited range.

Please refer to FIGS. 10 to 12, in which the quick release connecting device according to the second preferred embodiment of the present invention is shown. As shown, in the second preferred embodiment, the actuating retainer 1 and the fixing member 2 are held to each other via the pin connection means 3 to allow limited rotating of them relative to each other, and accordingly, the retaining section 12 is rotatably engaged with or released from the first object 5. More specifically, the actuating retainer 1 is also internally provided with a pin connection slot 13, which communicates with the receiving space 11, and the pin connection means 3 is located in the pin connection slot 13. According to an operable embodiment, the pin connection slot 13 can be a locating hole 132 formed on one or two lateral walls of the receiving space 11. When the pin connection means 3 rotates in the locating hole 132, the actuating retainer 1 and the fixing member 2 are brought to rotate relative to each other within a limited angle.

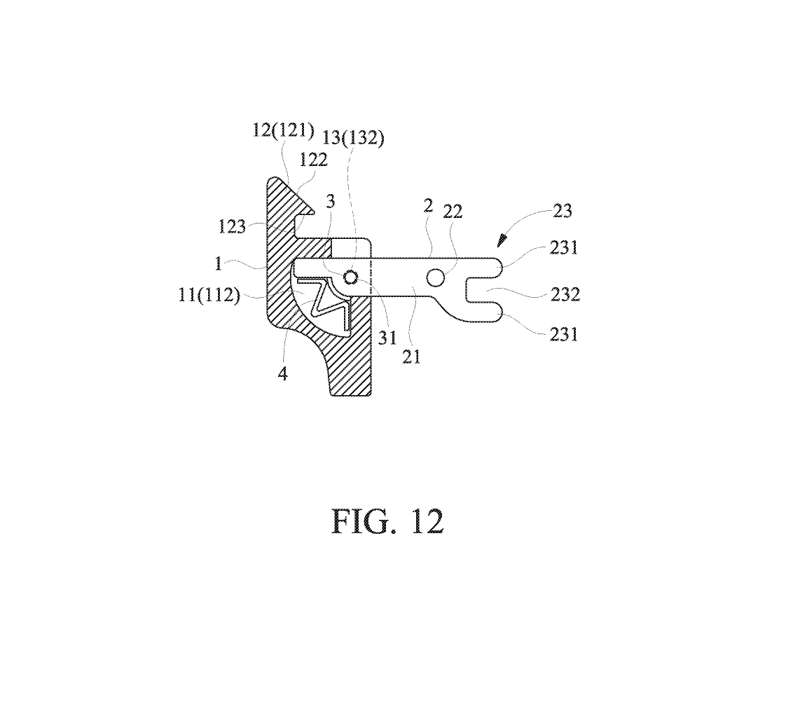

In the first preferred embodiment, as can be seen in FIGS. 2 and 4, and in the second preferred embodiment, as can be seen in FIGS. 10 and 12, the pin connection means 3 can include a cylindrical pin 31 integrally formed with or additionally assembled to the body portion 21 of the fixing member 2, and a pin holding hole 32 formed on the body portion 21 of the fixing member 2. The cylindrical pin 31 is inserted in, snapped fitted in, riveted to, expansion-fitted in, glued to or screwed into the pin holding hole 32. Alternatively, the pin connection means 3 can include a cylindrical pin 31 integrally formed with or additionally assembled to the actuating retainer 1, and a pin holding hole 32 formed on the body portion 21 of the fixing member 2. Similarly, the cylindrical pin 31 is inserted in, snapped fitted in, riveted to, expansion-fitted in, glued to or screwed into the pin holding hole 32. By transversely and slidably setting the cylindrical pin 31 of the pin connection means 3 in the long slide slot 131 as in the first preferred embodiment, or by transversely and rotatably setting the cylindrical pin 31 of the pin connection means 3 in the locating hole 132 as in the second preferred embodiment, it is able to achieve the limited sliding or the limited rotation, respectively, of the actuating retainer 1 and the fixing member 2 relative to each other. Alternatively, in the second variant of the first preferred embodiment as shown in FIG. 6, the pin connection means 3 includes a cylindrical pin 31 integrally formed with or additionally assembled to the actuating retainer 1 to transversely extend through the receiving space 11, and at least one pin holding hole 32 preferably formed on the actuating retainer 1 to communicate with the receiving space 11. Again, the cylindrical pin 31 is inserted in, snapped fitted in, riveted to, expansion-fitted in, glued to or screwed into the pin holding hole 32.

Please refer to FIGS. 1 to 12. In both of the first and the second preferred embodiment, the retaining section 12 on the actuating retainer 1 can be a hook 121 directed leftward (see FIGS. 1-11) or rightward (see FIG. 12) when viewing in front of the drawings. The hook 121 is preferably a triangular or wedge shaped hook protruded from the actuating retainer 1, and it includes a beveled guide surface 122 and a hooking surface 123 connected to a lower edge of the beveled guide surface 122. As can be seen in FIG. 13A, the beveled guide surface 122 allows the actuating retainer 1 to be conveniently pressed into the first object 5, and the hooking surface 123 can firmly abut on an inner side of the first object 5 after the beveled guide surface 122 has been moved into the first object 5.

In the first preferred embodiment shown in FIGS. 1 to 9, the fixing member 2 preferably includes at least one second push section 23. As illustrated in the drawings, the second push section 23 can be lying U-shaped to include two jaws 231 formed on an outer end thereof and a holding cavity 232 defined between the two jaws 231. Referring to FIG. 13A, the two jaws 231 and the holding cavity 232 of the second push section 23 can be used to hold the first object 5 thereto. When it is desired to release the second object 6 from the first object 5, simply turn the quick release connecting device as a lever to push the first object 5 out of the second push section 23, and the second object 6 can be easily released from the first object 5.

In the first preferred embodiment shown in FIGS. 1 to 9, the pivot portion 22 of the fixing member 2 is preferably a protruded block, a retaining block or a through hole integrally formed with or additionally assembled to the body portion 21. As shown in FIG. 13A, the quick release connecting device of the present invention can be movably connected to the second object 6 via the protruded block, the retaining block or the through hole. Preferably, the pivot portion 22 can be inserted in, snapped fitted onto, riveted to, expansion-fitted onto or screwed to the second object 6, so that the quick release connecting device and the second object 6 are rotatably connected to each other.

In the first preferred embodiment shown in FIGS. 1 to 9, the receiving space 11 in the actuating retainer 1 includes a straight and rectangular-sectioned slide space 111. The inner end of the body portion 21 of the fixing member 2 is extended into the slide space 111 and is slidably held therein via the pin connection means 3, so that the actuating retainer 1 and the fixing member 2 are able to slide relative to each other within a limited range. The elastic element 4 is preferably a coil spring, as shown in FIGS. 2 to 6, but it can also be an elastic plate or an elastic bar. The elastic element 4 is disposed in the slide space 111 with an end pressed against an inner wall surface of the slide space 111 and another end pressed against the body portion 21, such that the actuating retainer 1 and the fixing member 2 can slide relative to each other within a limited range and then return to their respective original position under the elastic force of the elastic element 4.

In the second preferred embodiment shown in FIGS. 10 to 12, the receiving space 11 in the actuating retainer 1 includes an arcuate slide space 112. The inner end of the body portion 21 of the fixing member 2 is extended into the arcuate slide space 112 and is rotatably held therein via the pin connection means 3, so that the actuating retainer 1 and the fixing member 2 are able to rotate relative to each other within a limited angle. The elastic element 4 is preferably a coil spring, as shown in FIG. 10, but it can also be an elastic plate as shown in FIG. 12 or an elastic bar (not shown). The elastic element 4 is disposed in the arcuate slide space 112 with an end pressed against an inner wall surface of the slide space 112 and another end pressed against the body portion 21, such that the actuating retainer 1 and the fixing member 2 can rotate relative to each other within a limited angle and then return to their respective original position under the elastic force of the elastic element 4.

The first object 5 can be a rack, a chassis, a cabinet for drawers, a window frame or other objects; and the second object 6 can be a circuit board, a drawer, a window or other objects. FIG. 13A shows the quick release connecting device according to the first preferred embodiment of the present invention is movably assembled to the second object 6 via the pivot portion 22 of the fixing member 2. Meanwhile, the retaining section 12 of the actuating retainer 1 and the second push section 23 of the fixing member 2 are detachably engaged with two opposite sides of the first object 5, so that the second object 6 is located in and sidewardly movably connected to the first object 5 via the quick release connecting device. When it is desired to separate the second object 6 from the first object 5, as indicated by FIG. 13B, simply push the first push section 14 of the actuating retainer 1 with one hand, so that the actuating retainer 1 slides toward the fixing member 2 by a limited range to separate the retaining section 12 from one side of the first object 5. Then, as shown in FIG. 13C, utilize the principle of leverage to push the quick release connecting device for the fixing member 2 to rotate about the pivot portion 22, bringing the second push section 23 to push the other side of the first object 5 away from it. At this point, the second object 6 can be pulled to slide out of the first object 5. Finally, as shown in FIG. 13D, when the second object 6 is separated from the first object 5 and the first push section 14 is no longer subjected to a push, the elastic element 4 automatically pushes the actuating retainer 1 to slide relative to the fixing member 5 back to its original position.

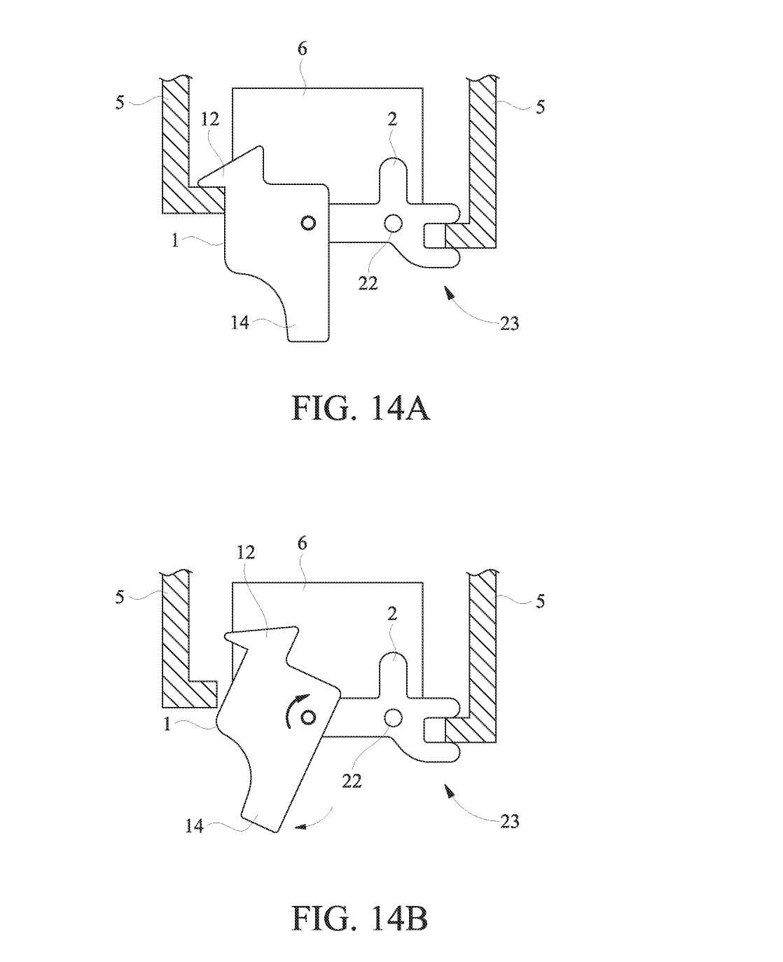

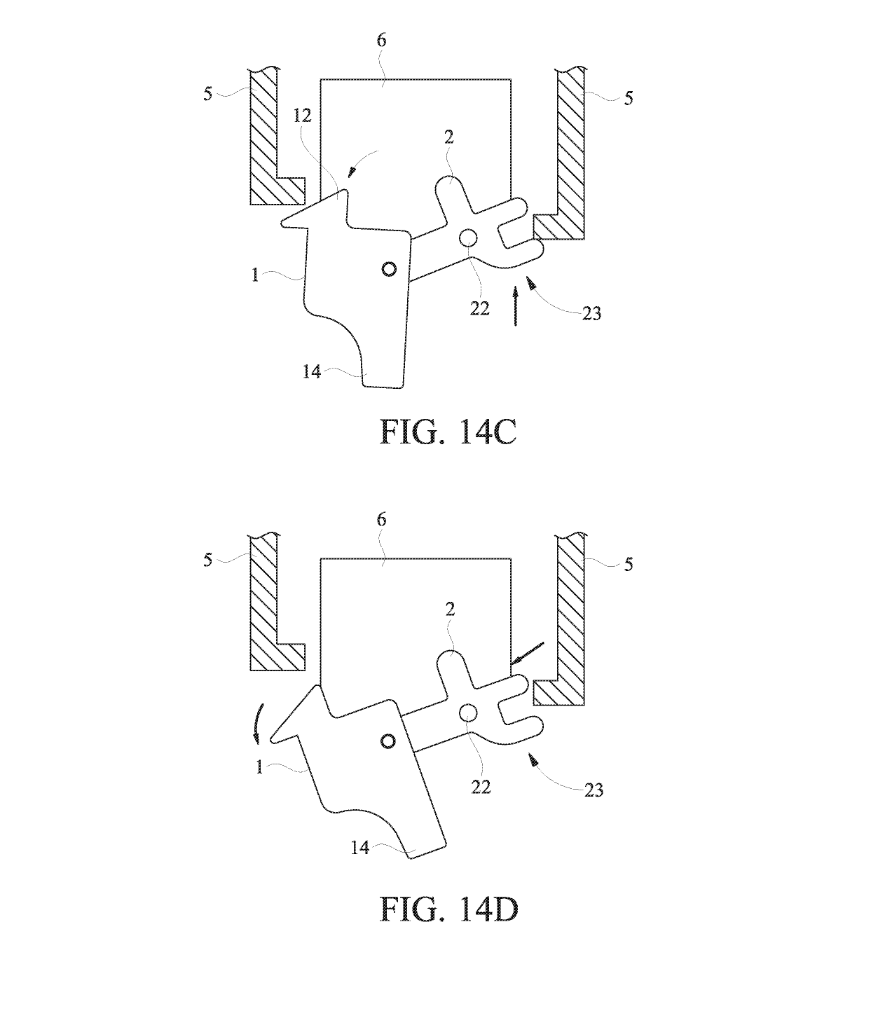

FIG. 14A shows the quick release connecting device according to the second preferred embodiment of the present invention is similarly movably assembled to the second object 6 via the pivot portion 22 of the fixing member 2. Meanwhile, the retaining section 12 of the actuating retainer 1 and the second push section 23 of the fixing member 2 are detachably engaged with two opposite sides of the first object 5, so that the second object 6 is located in and sidewardly movably connected to the first object 5 via the quick release connecting device. When it is desired to separate the second object 6 from the first object 5, as indicated by FIG. 14B, simply push the first push section 14 of the actuating retainer 1 with one hand, so that the actuating retainer 1 rotates relative to the fixing member 2 by a limited angle to separate the retaining section 12 from one side of the first object 5. Then, as shown in FIG. 14C, utilize the principle of leverage to push the quick release connecting device for the fixing member 2 to rotate about the pivot portion 22, bringing the second push section 23 to push the other side of the first object 5 away from it. At this point, the second object 6 can be pulled to slide out of the first object 5. Finally, as shown in FIG. 14D, when the second object 6 is separated from the first object 5 and the first push section 14 is no longer subjected to a push, the elastic element 4 automatically pushes the actuating retainer 1 to rotate relative to the fixing member 5 back to its original position.

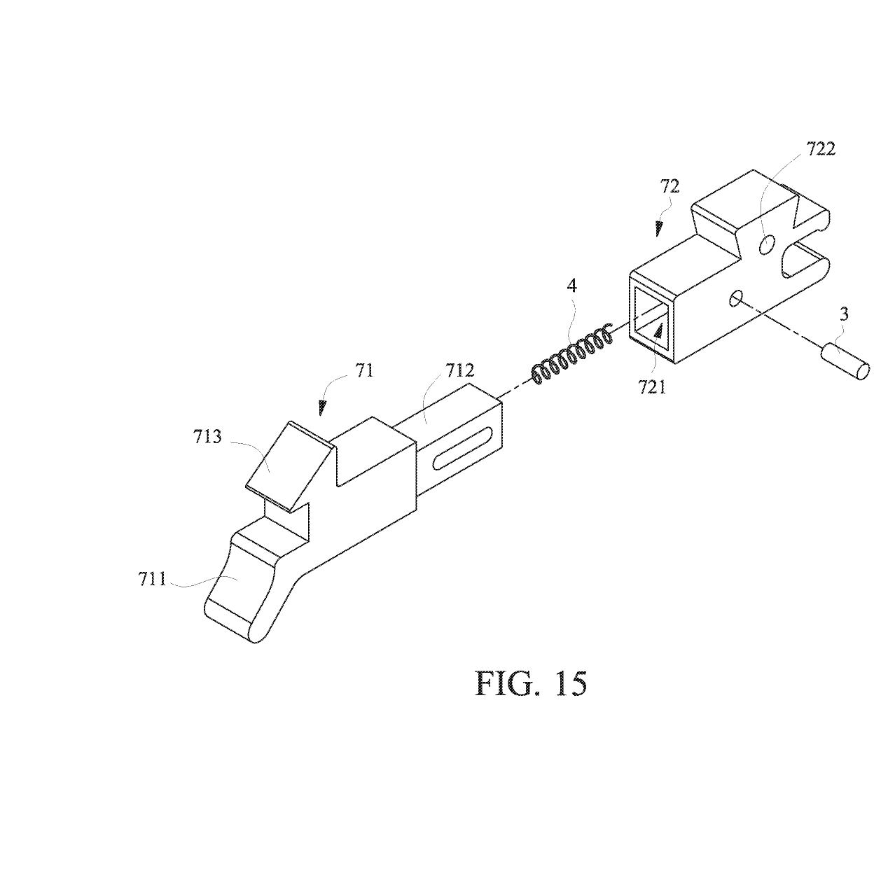

Please refer to FIG. 15, which is an exploded perspective view of a quick release connecting device 7 according to a third preferred embodiment of the present invention. The quick release connecting device 7 includes an actuating retainer 71, a fixing member 72 movably assembled to the actuating retainer 71, pin connection means 3, and an elastic element 4. The actuating retainer 71 includes at least one first push section 711, a body portion 712, and a retaining section 713 for detachably engaging with a first object 5. The fixing member 72 internally defines a receiving space 721 and includes a pivot portion 722 formed on an outer side of the receiving space 721. The body portion 712 is movably received in the receiving space 721, and the pivot portion 722 is used to movably connect to a second object (not shown in FIG. 15). The pin connection means 3 enables connection of the receiving space 721 of the fixing member 72 to the body portion 712 of the actuating retainer 71, such that the actuating retainer 71 and the fixing member 72 are movable relative to each other within a limited range. The elastic element 4 is disposed in the receiving space 721 with an end pressed against an inner wall surface of the receiving space 721 and another opposite end against the body portion 712. In this manner, the elastic element 4 enables and controls the limited movement of the actuating retainer 71 and the fixing member 72 relative to each other, and can elastically push the actuating retainer 71 and the fixing member 72 back to their original positions.

In addition, the retaining section 713 can be in the form of a hook, a recessed section, a protruded section, a stepped section, a flat surface, a cambered surface, or a curved surface.

Please refer to FIG. 16, which show a quick release connecting device 7 according to a fourth preferred embodiment of the present invention. In the illustrated fourth preferred embodiment, the pivot portion 722 (refer to the pivot portion 722 in FIG. 15) has a movable pivot member 723 mounted thereto for coupling with the second object 6. The pivot member 723 (or the fixing member 72) includes a shaft 724 movably assembled thereto via second pin connection means 725. An elastic element 73 is fitted on around the pivot portion 722 or the pivot member 723 with two ends pressed against the pivot member 723 and the fixing member 72 of the quick release connecting device 7. The pivot member 723 includes a coupling section 726 for screwing onto, snap-fitted on, expansion-fitted on, welded to or riveted to the second object 6. Further, the fixing member 72 includes a limiting section 727 and the pivot member 723 includes a corresponding limiting section 728. When the fixing member is moved or rotated, the limiting section 727 and the corresponding limiting section 728 can limit or stop each other at a specific location. The actuating retainer 71 or the body portion 712 thereof includes a shoulder section 714 for limiting a distance by which the actuating retainer 71 or the body portion 712 is allowed to move into the receiving space 721.

In addition, the first push section 711 can be in the form of a boss, a bore, a recess, a protrusion, a fastener, a stepped section, an anti-slip section, a flat section, a hook section or a cambered section.

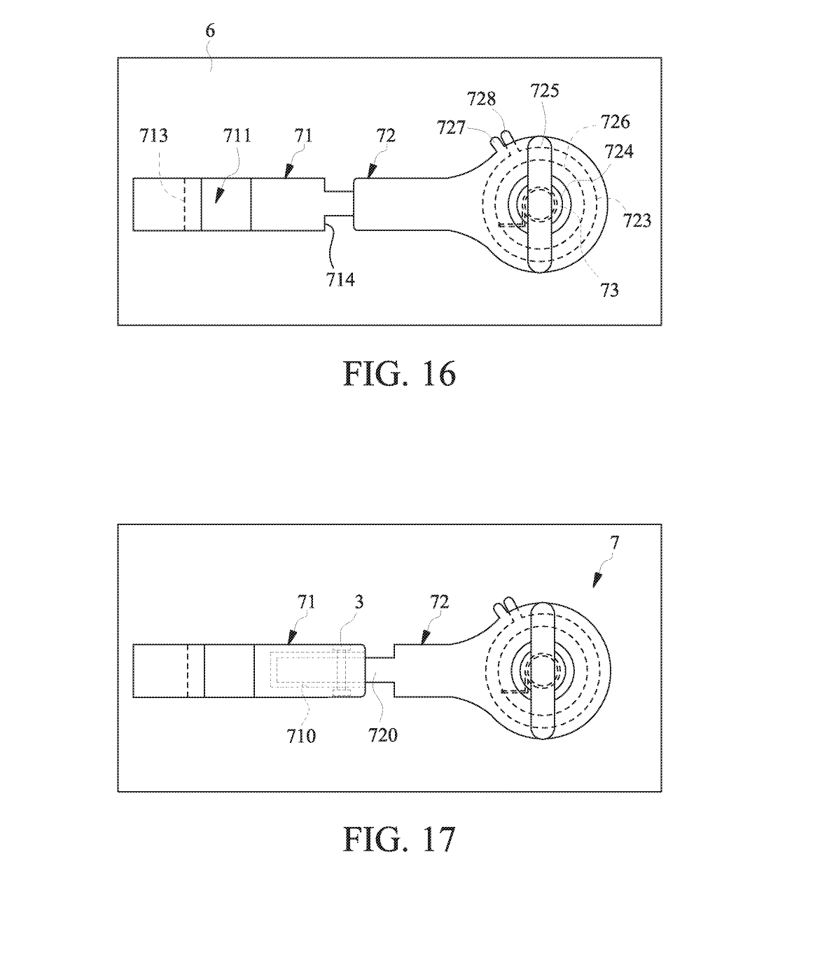

Please refer to FIG. 17, which show a quick release connecting device 7 according to a fifth preferred embodiment of the present invention. In the illustrated fifth preferred embodiment, the actuating retainer 71 of the quick release connecting device 7 defines a receiving space 710, and the fixing member 72 includes a body portion 720 movably received in the receiving space 710; and the pin connection means 3 enables connection of the receiving space 710 of the actuating retainer 71 to the body portion 720 of the fixing member 72, such that the actuating retainer 71 and the fixing member 72 are movable relative to each other within a limited range.

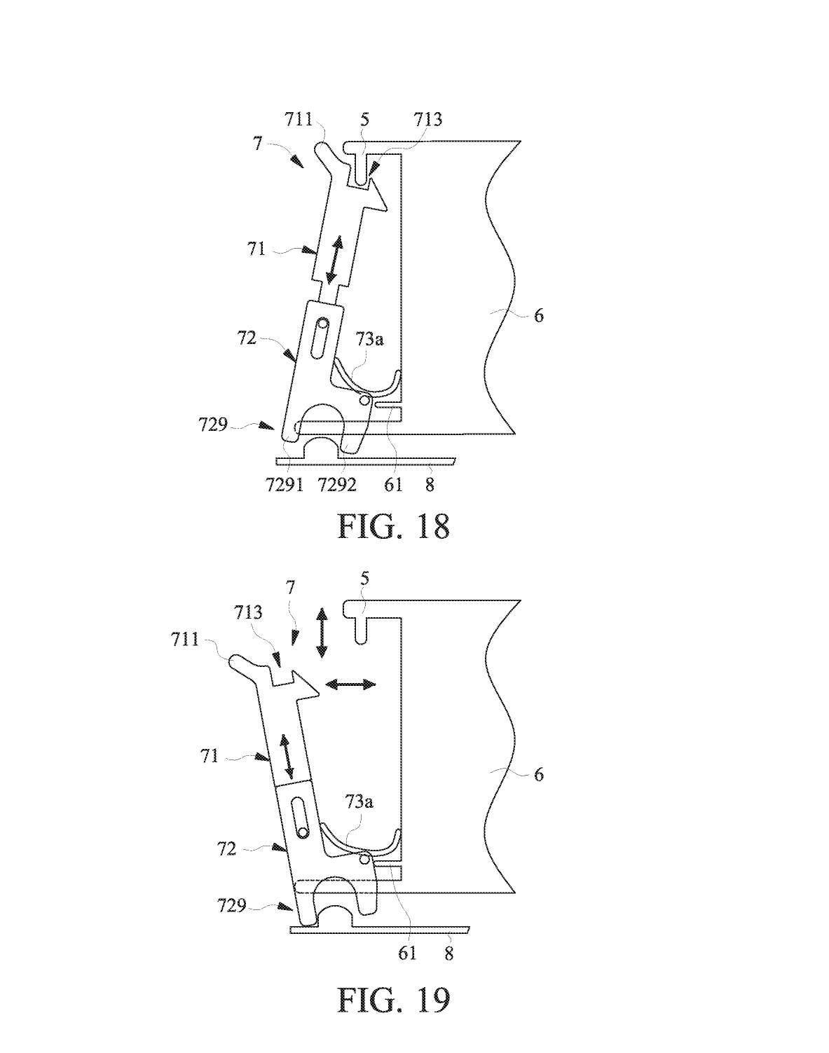

Please refer to FIGS. 18 and 19, which show a quick release connecting device 7 according to a sixth preferred embodiment of the present invention. In the illustrated sixth preferred embodiment, the first object 5 and the second object 6 can be integrally formed, assembled together, or two independent objects; the second object 6 can be assembled to a fourth object 9 to form a modular object; or the quick release connecting device 7 and the second object 6 can be assembled together to form a module with an elastic element 73a pressing an end against the fixing member 72 of the quick release connecting device 7 and another end against the second object 6, such that the fixing member 72 under a spring force of the elastic element 73a is either automatically sprung back to its original position or be limited to a fixed position. The fixing member 72 includes a second push section 729 having a first push part 7291 and a second push part 7292. The first push part 7291 or the second push part 7292 can be used to push against a third object 8. The push of the second push section 729 against the third object 8 causes a lever displacement, a rotary displacement or a limited displacement of the third object 8, so as to open, close, forward move or backward move the third object 8. Alternatively, the first push part 7291 or the second push part 7292 can also push the third object 8 to displace the same. The second object 6 includes a limiting section 61 for limiting a distance or an angle by which the second push section 729 can be moved or rotated, respectively. Or, in practical use of the quick release connecting device 7, the first push part 7291 and the second push part 7292 can be first subjected to a rotational or a non-rotational displacement to be located in front of, behind or in the middle of a location where the third object 8 will be pushed against or interfered with, so that the first push part 7291 or the second push part 7292 having been rotationally or non-rotationally displaced can push against or interfere with the third object 8, enabling the second push section 729 to open, close, forward move or backward move the third object 8 through a lever displacement, a rotary displacement or a limited displacement of the third object 8.

In addition, the second push section 729 can be in the form of a protruded section, a recessed section, a through bore, a stepped section, a flat section, a cambered section, a hook section or a curved section.

Further, when operating the first push section 711 of the actuating retainer 71 to compress the first push section 711 toward the fixing member 72, an overall travel of the quick release connecting device 7 is shortened and the retaining section 713 is separated from the first object 5 to pull the second object 6.

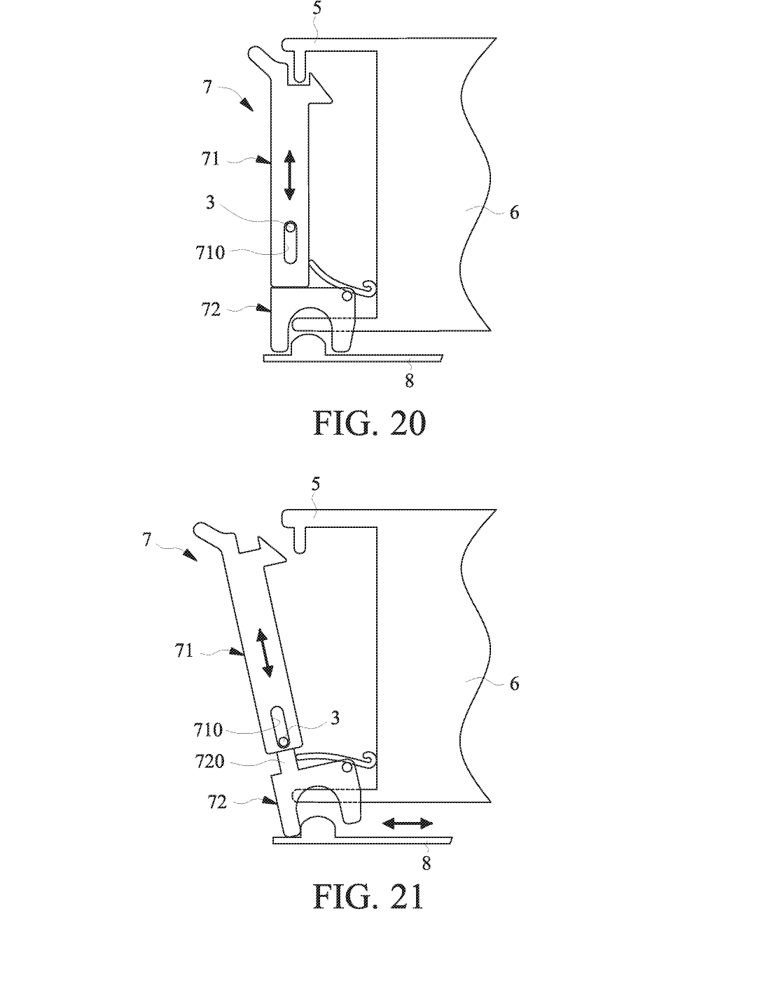

Please refer to FIGS. 20 and 21, which show a quick release connecting device 7 according to a seventh preferred embodiment of the present invention. In the illustrated seventh preferred embodiment, the actuating retainer 71 of the quick release connecting device 7 defines a receiving space 710, and the fixing member 72 includes a body portion 720 movably received in the receiving space 710; and the pin connection means 3 enables connection of the receiving space 710 of the actuating retainer 71 to the body portion 720 of the fixing member 72, such that the actuating retainer 71 and the fixing member 72 are movable relative to each other within a limited range. Further, an elastic element (not shown) is disposed in the receiving space 710 with an end of the elastic element pressed against an inner wall surface of the receiving space 710 and another opposite end against the body portion 720. In this manner, the elastic element enables and controls the limited movement of the actuating retainer 71 and the fixing member 72 relative to each other, and can elastically push the actuating retainer 71 and the fixing member 72 back to their original positions. That is, the seventh preferred embodiment can achieve the same effect as the fifth preferred embodiment.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A quick release connecting device, comprising:
an actuating retainer internally defining a receiving space, and including at least one first push section and a retaining section for detachably engaging with a first object;
a fixing member movably assembled to the actuating retainer and including a body portion and a pivot portion formed on an outer end of the body portion; the body portion having an inner end movably associated with the receiving space of the actuating retainer, and the pivot portion being located outside the receiving space for detachably connecting with a second object;
pin connection means enabling connection of the body portion of the fixing member to the receiving space of the actuating retainer, such that the actuating retainer and the fixing member are movable relative to each other within a limited range; and
an elastic element being disposed in the receiving space of the actuating retainer with an end pressed against an inner wall surface of the receiving space and another opposite end against the body portion of the fixing member; and
wherein the elastic element enables and controls limited movement of the actuating retainer and the fixing member relative to each other, and can push the actuating retainer and the fixing member back to their original positions when the second object is separated from the first object and the first push section of the actuating retainer is no longer subjected to a push; or
the actuating retainer including at least one first push section, a body portion and a retaining section for detachably engaging with a first object;
the fixing member internally defining a receiving space and including a pivot portion formed on an outer side of the receiving space; the body portion of the actuating retainer being movably received in the receiving space of the fixing member, and the pivot portion being used to movably connect to a second object;
the pin connection means enabling connection of the receiving space of the fixing member to the body portion of the actuating retainer, such that the actuating retainer and the fixing member are movable relative to each other within a limited range; and
the elastic element being disposed in the receiving space of the fixing member with an end pressed against an inner wall surface of the receiving space and another opposite end against the body portion of the actuating retainer, such that the elastic element enables and controls the limited movement of the actuating retainer and the fixing member relative to each other and can elastically push the actuating retainer and the fixing member back to their original positions; and
the fixing member including a second push section having a first push part or a second push part; the first push part or the second push part being able to push against a third object; and the push of the second push section against the third object causing a lever displacement, a rotary displacement or a limited displacement of the third object to thereby open, close, forward move or backward move the third object.

2. The quick release connecting device as claimed in claim 1, wherein the retaining section on the actuating retainer can be any one of a hook, a recessed section, a protruded section, a stepped section, a flat surface, a cambered surface and a curved surface directed leftward or rightward or forward relative to the actuating retainer.

3. The quick release connecting device as claimed in claim 2, wherein the retaining section includes a beveled guide surface for guiding the actuating retainer into the first object to engage with the first object.

4. The quick release connecting device as claimed in claim 1, wherein the pivot portion has a pivot member movably mounted thereto for coupling with the second object.

5. The quick release connecting device as claimed in claim 4, wherein the pivot member includes a shaft movably assembled thereto.

6. The quick release connecting device as claimed in claim 5, wherein the pivot member and the shaft are movably assembled together via second pin connection means, or the fixing member and the shaft are movably assembled together via second pin connection means.

7. The quick release connecting device as claimed in claim 4, wherein the pivot portion or the pivot member has an elastic element fitted thereon, the elastic element either having two ends pressed against the pivot member and the fixing member of the quick release connecting device or having two ends pressed against the quick release connecting device and the second object, such that the fixing member under a spring force of the elastic element is either automatically sprung back to its original position or be limited to a fixed position.

8. The quick release connecting device as claimed in claim 4, wherein the fixing member includes a limiting section and the pivot member includes a corresponding limiting section; and the limiting section and the corresponding limiting section being able to limit or stop each other at a specific location when the fixing member is moved or rotated.

9. The quick release connecting device as claimed in claim 1, wherein the first push section is selected from the group consisting of a boss, a bore, a recess, a protrusion, a fastener, a stepped section, an anti-slip section, a flat section and a cambered section.

10. The quick release connecting device as claimed in claim 4, wherein the pivot member includes a coupling section for screwing onto, snap-fitted on, expansion-fitted on, welded to or riveted to the second object.

11. The quick release connecting device as claimed in claim 1, wherein the actuating retainer or the body portion thereof includes a shoulder section for limiting a distance by which the actuating retainer or the body portion thereof is allowed to move into the receiving space of the fixing member.

12. The quick release connecting device as claimed in claim 1, wherein the first object and the second object can be integrally formed, assembled together, or two independent objects.

13. The quick release connecting device as claimed in claim 1, wherein the quick release connecting device and the second object are assembled together to form a module.

14. The quick release connecting device as claimed in claim 1, wherein the second object includes a limiting section for limiting a distance or an angle by which the second push section can be moved or rotated, respectively.

15. The quick release connecting device as claimed in claim 1, wherein, when the first push section of the actuating retainer is operable to compress the first push section toward the fixing member, such that an overall travel of the quick release connecting device is shortened and the retaining section of the actuating retainer is separated from the first object to pull the second object.

16. The quick release connecting device as claimed in claim 1, wherein the second push section can be any one of a protruded section, a recessed section, a through bore, a stepped section, a flat section, a cambered section, a hook section and a curved section.

17. A quick release connecting device, comprising:
an actuating retainer internally defining a receiving space, and including at least one first push section and a retaining section for detachably engaging with a first object;
a fixing member movably assembled to the actuating retainer and including a body portion and a pivot portion formed on an outer end of the body portion; the body portion having an inner end movably associated with the receiving space of the actuating retainer, and the pivot portion being located outside the receiving space for detachably connecting with a second object;
pin connection means enabling connection of the body portion of the fixing member to the receiving space of the actuating retainer, such that the actuating retainer and the fixing member are movable relative to each other within a limited range; and
an elastic element being disposed in the receiving space of the actuating retainer with an end pressed against an inner wall surface of the receiving space and another opposite end against the body portion of the fixing member; and
wherein the elastic element enables and controls limited movement of the actuating retainer and the fixing member relative to each other, and can push the actuating retainer and the fixing member back to their original positions when the second object is separated from the first object and the first push section of the actuating retainer is no longer subjected to a push; or
the actuating retainer including at least one first push section, a body portion and a retaining section for detachably engaging with a first object;
the fixing member internally defining a receiving space and including a pivot portion formed on an outer side of the receiving space; the body portion of the actuating retainer being movably received in the receiving space of the fixing member, and the pivot portion being used to movably connect to a second object;
the pin connection means enabling connection of the receiving space of the fixing member to the body portion of the actuating retainer, such that the actuating retainer and the fixing member are movable relative to each other within a limited range; and
the elastic element being disposed in the receiving space of the fixing member with an end pressed against an inner wall surface of the receiving space and another opposite end against the body portion of the actuating retainer, such that the elastic element enables and controls limited movement of the actuating retainer and the fixing member relative to each other and can elastically push the actuating retainer and the fixing member back to their original positions; and
the fixing member including a second push section having a first push part or a second push part; in practical use of the first push part or the second push part, the first push part or the second push part being first subjected to a rotational or a non-rotational displacement to be located in front of, behind or in the middle of a location where a third object will be pushed against or interfered with, such that the first push part or the second push part having been rotationally or non-rotationally displaced can push against or interfere with the third object, enabling the second push section to open, close, forward move or backward move the third object through a lever displacement, a rotary displacement or a limited displacement of the third object.

18. The quick release connecting device as claimed in claim 17, wherein the retaining section on the actuating retainer can be any one of a hook, a recessed section, a protruded section, a stepped section, a flat surface, a cambered surface and a curved surface directed leftward or rightward or forward relative to the actuating retainer.

19. The quick release connecting device as claimed in claim 18, wherein the retaining section includes a beveled guide surface for guiding the actuating retainer into the first object to engage with the first object.

20. The quick release connecting device as claimed in claim 17, wherein the pivot portion has a pivot member movably mounted thereto for coupling with the second object.

21. The quick release connecting device as claimed in claim 20, wherein the pivot member includes a shaft movably assembled thereto.

22. The quick release connecting device as claimed in claim 21, wherein the pivot member and the shaft are movably assembled together via second pin connection means, or the fixing member and the shaft are movably assembled together via second pin connection means.

23. The quick release connecting device as claimed in claim 20, wherein the pivot portion or the pivot member has an elastic element fitted thereon, the elastic element either having two ends pressed against the pivot member and the fixing member of the quick release connecting device or having two ends pressed against the quick release connecting device and the second object, such that the fixing member under a spring force of the elastic element is either automatically sprung back to its original position or be limited to a fixed position.

24. The quick release connecting device as claimed in claim 20, wherein the fixing member includes a limiting section and the pivot member includes a corresponding limiting section; and the limiting section and the corresponding limiting section being able to limit or stop each other at a specific location when the fixing member is moved or rotated.

25. The quick release connecting device as claimed in claim 17, wherein the first push section is selected from the group consisting of a boss, a bore, a recess, a protrusion, a fastener, a stepped section, an anti-slip section, a flat section, a hook section and a cambered section.

26. The quick release connecting device as claimed in claim 20, wherein the pivot member includes a coupling section for screwing onto, snap-fitted on, expansion-fitted on, welded to or riveted to the second object.

27. The quick release connecting device as claimed in claim 17, wherein the actuating retainer or the body portion thereof includes a shoulder section for limiting a distance by which the actuating retainer or the body portion thereof is allowed to move into the receiving space of the fixing member.

28. The quick release connecting device as claimed in claim 17, wherein the first object and the second object can be integrally formed, assembled together, or two independent objects.

29. The quick release connecting device as claimed in claim 17, wherein the quick release connecting device and the second object are assembled together to form a module.

30. The quick release connecting device as claimed in claim 17, wherein the second object includes a limiting section for limiting a distance or an angle by which the second push section can be moved or rotated, respectively.

31. The quick release connecting device as claimed in claim 17, wherein the first push section of the actuating retainer is operable to compress the first push section toward the fixing member, such that an overall travel of the quick release connecting device is shortened and the retaining section of the actuating retainer is separated from the first object to pull the second object.

32. The quick release connecting device as claimed in claim 17, wherein the second push section can be any one of a protruded section, a recessed section, a through bore, a stepped section, a flat section, a cambered section, a hook section and a curved section.
